(19) United States
(12) Patent Application Publication
(10) Pub. No.: US 2015/0131254 A1
(43) Pub. Date: May 14, 2015

(54) PRINTED CIRCUIT BOARD, SEMICONDUCTOR PACKAGE HAVING THE SAME AND METHOD FOR MANUFACTURING THE SAME

(71) Applicant: SAMSUNG ELECTRO-MECHANICS CO., LTD., Suwon-si (KR)

(72) Inventors: Min-Sung KIM, Suwon-si (KR); Jun-Hyung SON, Suwon-si (KR)

(73) Assignee: SAMSUNG ELECTRO-MECHANICS CO., LTD., Suwon-si (KR)

(21) Appl. No.: 14/228,250

(22) Filed: Mar. 28, 2014

(30) Foreign Application Priority Data
Nov. 13, 2013 (KR) 10-2013-0137814

(51) Int. Cl. H05K 1/02; H05K 3/18; H05K 3/46; H05K 3/06; H05K 1/11; H05K 1/18

(52) U.S. Cl. CPC H05K 1/0271; H05K 1/11; H05K 1/181; H05K 3/4611; H05K 3/06; H05K 3/188
USPC 361/783; 216/13

(57) ABSTRACT

The present invention discloses a printed circuit board, a semiconductor package having the same, and a method for manufacturing the same. A printed circuit board according to an aspect of the present invention includes: a package board including a mounting area and a peripheral area, the mounting area having a semiconductor chip mounted therein, the peripheral area surrounding the mounting area; a first central circuit pattern formed in the mounting area on one surface of the package board; a second central circuit pattern formed in the mounting area on the other surface of the package board and having a greater thickness than the first central circuit pattern; a first peripheral circuit pattern formed in the peripheral area on the one surface of the package board; and a second peripheral circuit pattern formed in the peripheral area on the other surface of the package board and having a greater thickness than the second peripheral circuit pattern.

### CROSS-REFERENCE TO RELATED APPLICATIONS

This application claims the benefit of Korean Patent Application No. 10-2013-0137814, filed with the Korean Intellectual Property Office on Nov. 13, 2013, the disclosure of which is incorporated herein by reference in its entirety.

### BACKGROUND

1. Technical Field

The present invention relates to a printed circuit board, a semiconductor package having the same, and a method for manufacturing the same.

2. Background Art

A semiconductor package can be formed by mounting a semiconductor chip on a printed circuit board. The semiconductor chip can be joined with a circuit pattern of the printed circuit pattern by solder. This fabricated semiconductor package can be mounted on the printed circuit board, for example, a mainboard, which can be also joined with the semiconductor package by solder.

The joint between the printed circuit board and the semiconductor chip can be carried out through a reflow process using a high heat. In such a case, warpage can be made in the semiconductor package manufactured through the reflow process because the coefficient of thermal expansion is different between the printed circuit board and the semiconductor chip. The warpage in the semiconductor package can affect the joint between the semiconductor package and the mainboard.

The related art of the present invention is disclosed in Korea Patent Publication No. 1997-0058409 (laid open on Jul. 31, 1997).

### SUMMARY

The present invention provides a printed circuit board and a method for manufacturing the printed circuit board that can reduce warpage in a semiconductor package, and a semiconductor package with reduced warpage by including said printed circuit board.

An aspect of the present invention provides a printed circuit board, which includes: a package board including a mounting area and a peripheral area, the mounting area having a semiconductor chip mounted therein, the peripheral area surrounding the mounting area; a first central circuit pattern formed in the mounting area on one surface of the package board; a second central circuit pattern formed in the mounting area on the other surface of the package board and having a greater thickness than the first central circuit pattern; a first peripheral circuit pattern formed in the peripheral area on the one surface of the package board; and a second peripheral circuit pattern formed in the peripheral area on the other surface of the package board and having a greater thickness than the second peripheral circuit pattern.

A difference in thickness between the first central circuit pattern and the second central circuit pattern can be same as a difference in thickness between the first peripheral circuit pattern and the second peripheral circuit pattern.

A thickness of the first central circuit pattern and a thickness of the second peripheral circuit pattern can be identical with each other, and a thickness of the second central circuit pattern and a thickness of the first peripheral circuit pattern can be identical with each other.

The semiconductor chip can be arranged in the mounting area on the one surface of the package board, and the first central circuit pattern can be electrically connected with an electrode of the semiconductor chip by solder.

The electrode of the semiconductor chip can be formed on a lower surface of the semiconductor chip, and the semiconductor chip can be warped to be bulged downwardly when temperature rises. The mounting area can be warped to be bulged toward the other surface of the package board, in a same direction as the semiconductor is warped, when temperature rises. The peripheral area can be warped to be bulged toward the one surface of the package board, in an opposite direction to warpage of the semiconductor, when temperature rises.

The package board can include: a plurality of insulation layers; and an internal circuit pattern formed in between the plurality of insulation layers.

Another aspect of the present invention provides a semiconductor package, which includes: a semiconductor chip having an electrode formed thereon; a package board including a mounting area and a peripheral area, the mounting area having the semiconductor chip mounted therein, the peripheral area surrounding the mounting area; a first central circuit pattern formed in the mounting area on one surface of the package board; a second central circuit pattern formed in the mounting area on the other surface of the package board and having a greater thickness than the first central circuit pattern; a first peripheral circuit pattern formed in the peripheral area on the one surface of the package board; and a second peripheral circuit pattern formed in the peripheral area on the other surface of the package board and having a greater thickness than the second peripheral circuit pattern.

A difference in thickness between the first central circuit pattern and the second central circuit pattern can be same as a difference in thickness between the first peripheral circuit pattern and the second peripheral circuit pattern.

A thickness of the first central circuit pattern and a thickness of the second peripheral circuit pattern can be identical with each other, and a thickness of the second central circuit pattern and a thickness of the first peripheral circuit pattern can be identical with each other.

The semiconductor chip can be arranged in the mounting area on the one surface of the package board, and the first central circuit pattern can be electrically connected with an electrode of the semiconductor chip by solder.

The electrode of the semiconductor chip can be formed on a lower surface of the semiconductor chip, and the semiconductor chip is warped to be bulged downwardly when temperature rises. The mounting area can be warped to be bulged toward the other surface of the package board, in a same direction as the semiconductor is warped, when temperature rises. The peripheral area can be warped to be bulged toward the one surface of the package board, in an opposite direction to warpage of the semiconductor, when temperature rises.

The package board can include: a plurality of insulation layers; and an internal circuit pattern formed in between the plurality of insulation layers.

Yet another aspect of the present invention provides a method for manufacturing a printed circuit board that includes: providing a package board, the package board including a mounting area and a peripheral area, the mounting area having a semiconductor chip mounted therein, the peripheral area surrounding the mounting area; forming a first external circuit pattern and a second external circuit pattern on one surface and the other surface of the package board, respectively; and removing a partial thickness of the first external circuit pattern placed in the mounting area on the one surface of the package board and removing a partial thickness of the second external circuit pattern placed in the peripheral area on the other surface of the package board.

The first external circuit pattern and the second external circuit pattern can be formed in a same thickness.

The first external circuit pattern and the second external circuit pattern can be removed by a same thickness.

The forming of the first external circuit pattern and the second external circuit pattern can include: forming a resist on the one surface and the other surface of the package board, the resist having an opening formed therein so as to correspond to a position of the first external circuit pattern and the second external circuit pattern; and filling in the opening with a conductive material by plating.

The removing of the partial thickness of the first external circuit pattern and the second external circuit pattern can be carried out by etching.

### BRIEF DESCRIPTION OF THE DRAWINGS

FIG. 1 is a cross-sectional view showing a semiconductor package in accordance with an embodiment of the present invention.

FIG. 2 is a top view showing the semiconductor package in accordance with an embodiment of the present invention.

FIG. 3 is a cross-sectional view briefly showing a printed circuit board in the semiconductor package in accordance with an embodiment of the present invention.

FIG. 4 and FIG. 5 show how warpage tends to be made in the semiconductor package in accordance with an embodiment of the present invention.

FIG. 6 is a flow diagram showing a method for manufacturing a printed circuit board in accordance with another embodiment of the present invention.

FIGS. 7 to 9 are cross-sectional views showing the method for manufacturing a printed circuit board in accordance with another embodiment of the present invention.

### DETAILED DESCRIPTION

Hereinafter, a printed circuit board, a semiconductor package having the printed circuit board and a method for manufacturing the printed circuit board in accordance with certain embodiments of the present invention will be described in detail with reference to the accompanying drawings. In describing the present invention with reference to the accompanying drawings, any identical or corresponding elements will be assigned with same reference numerals, and no redundant description thereof will be provided.

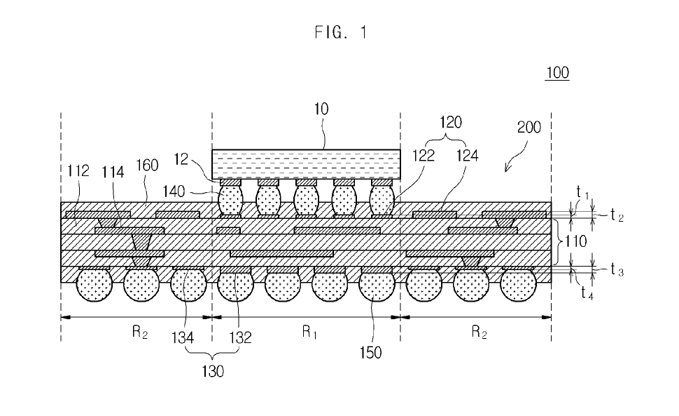

Referring to FIG. 1 to FIG. 3, a printed circuit board 200 in accordance with an embodiment of the present invention includes a package board 110 constituted with a mounting area R1 and a peripheral area R2, a first central circuit pattern 122 and a second central circuit pattern 132 formed, respectively, on either surface of the mounting area R1 of the package board 110, and a first peripheral circuit pattern 124 and a second peripheral circuit pattern 134 formed, respectively, on either surface of the peripheral area R2 of the package board 110. A semiconductor package 100 in accordance with an embodiment of the present invention has the printed circuit board 200 mounted on a semiconductor chip 10.

According to the present embodiment, the first central circuit pattern 122 and the second central circuit pattern 132 are formed in different thicknesses t1, t3 on either surface of the mounting area R1 of the package board 110, and the first peripheral circuit pattern 124 and the second peripheral circuit pattern 134 are formed in different thicknesses t2, t4 on either surface of the peripheral area R2 of the package board 110, but by forming the second central circuit pattern 132 to be thicker than the first central circuit pattern 122 and forming the second peripheral circuit pattern 134 to be thinner than the first peripheral circuit pattern 124, warpage of the semiconductor package 100 manufactured by a reflow process can be reduced at room temperature.

The structure and principle of the present embodiment will be described in more detail below with reference to FIGS. 1 to 5.

As illustrated in FIG. 1, the semiconductor chip 10 can have a plurality of electrodes 12 formed on a lower surface thereof and can be arranged in the mounting area R1 on one surface of the package board 110. The electrodes 12 of the semiconductor chip 10 can be electrically connected with the printed circuit board 200, specifically, with the first central circuit pattern 122, by solder 140.

Joining between the electrodes 12 of the semiconductor chip 10 and the first central circuit pattern 122 can be made by a reflow process, which applies high-temperature heat to the solder 140. The semiconductor chip 10 can be made of a material such as silicon, and the electrodes 12 can be made of a metal such as copper. Since the metal such as copper has a higher coefficient of thermal expansion than the material such as silicon, heating the semiconductor chip 10 for the reflow process can cause the semiconductor chip 10 to warp toward the lower surface, on which the electrodes 12 are formed. That is, the semiconductor chip 10 can be bulged toward the bottom of the semiconductor chip 10 (see FIG. 4).

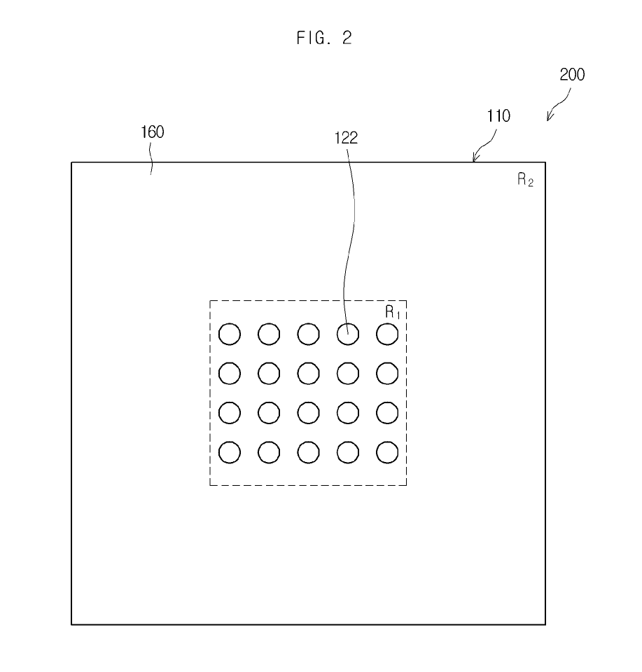

As illustrated in FIGS. 1 and 2, the package board 110 can be divided into the mounting area R1, on which the semiconductor chip 10 is mounted, and the peripheral area R2, which surrounds peripheral portions of the mounting area R1. As shown in FIG. 1, the mounting area R1 of the package board 110 is configured to correspond to a cross-sectional area of the semiconductor chip 10, and thus the mounting area R1 is completely covered by the semiconductor chip 10.

The mounting area R1 and the peripheral area R2 are areas demarcated virtually by considering a location where the semiconductor chip 10 is mounted, and are not individual elements that have real boundaries. Rather, as shown in FIG. 1, each of insulation layers 112 constituting the package board 110 forms a single layer. In FIG. 2, which is the top view of the printed circuit board 200, the mounting area R1 is illustrated with dotted lines in order to clarify that the mounting area R1 is not an individual, separate element.

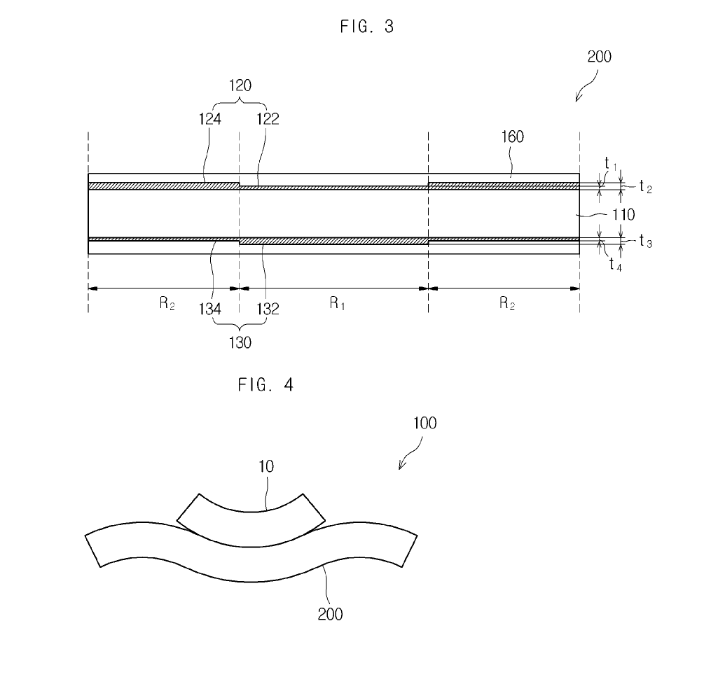

Moreover, as illustrated in FIG. 1, the package board 110 can be constituted with the plurality of insulation layers 112 that are laminated on one another and internal circuit patterns 114 formed in between the insulation layers 112. In addition, as illustrated in FIG. 3, the package board 110 constituted with a single layer and having two layers of circuits can be also included in the scope of the present invention. In the case where the package board 110 includes the internal circuit patterns 114, as shown in FIG. 1, the internal circuit patterns 114 can have a same thickness with one another.

The first central circuit pattern 122 and the second central circuit pattern 132 can be formed in the different thicknesses t1, t3 on either surfaces of the mounting area R1. FIG. 3 is for illustrating this relation of different thicknesses more clearly, and a first external circuit pattern 120 and a second external pattern 130 are illustrated in simple contiguous layer structures.

As shown in FIG. 1 and FIG. 3, the first central circuit pattern 122 can be formed on the mounting area R1 on one surface of the package board 110, and the second central circuit pattern 132 can be formed on the mounting area R1 on the other surface of the package board 110, with the thickness t3 of the second central circuit pattern 132 being greater than the thickness t1 of the first central circuit pattern 122.

As the thickness t1 of the first central circuit pattern 122 formed on one surface of the mounting area R1 of the package board 110 on which the semiconductor chip 10 is mounted is smaller than the thickness t3 of the second central circuit pattern 132 formed on the other surface of the mounting area R1, heating the printed circuit board 200 together with the semiconductor chip 10 for the reflow process can make the package board 110 warp in the direction of the other surface, i.e., downwards, when temperature rises in the mounting area R1 of the package board 110, as illustrated in FIG. 4. Since the first central circuit pattern 122 and the second central circuit pattern 132 are made of a metal, such as copper, the thermal expansion will be increased with an increased amount of the metal, and thus the bulging warpage occurs in the direction of the other surface of the package board 110 where there is a greater amount of metal.

As described above, the semiconductor chip 10 can be bulged toward the lower surface thereof, where the electrodes 12 are formed, during the reflow process. Accordingly, by performing the reflow process after arranging the semiconductor chip 10 to have the lower surface thereof face the first central circuit pattern 122 of the mounting area R1, the semiconductor chip 10 and the mounting area R1 of the package board 110 can have a same warpage, and a more reliable contact can be made between the electrodes 12 of the semiconductor chip 10 and the first central circuit pattern 122.

Although it is described in the present embodiment that bulging warpage is occurred downwardly in the semiconductor chip 10 by the electrodes 12 of the semiconductor chip 10 and that the semiconductor chip 10 is mounted on the first central circuit pattern 122 of the mounting area R1 in consideration of this warping tendency, it is also possible that the semiconductor chip 10 is warped to be bulged upwardly due to, for example, an internal circuit structure. In such a case, the semiconductor chip 10 can be mounted on the second central circuit pattern 132 of the mounting area R1, and it shall be appreciated that this structure is also included in the scope of the present invention.

As illustrated in FIG. 1 and FIG. 3, the first peripheral circuit pattern 124 can be formed on the peripheral area R2 on one surface of the package board 110, and the second peripheral circuit pattern 134 can be formed on the peripheral area R2 on the other surface of the package board 110, with the thickness t4 of the second peripheral circuit pattern 134 being smaller than the thickness t2 of the first peripheral circuit pattern 124.

As the thickness t2 of the first peripheral circuit pattern 124 formed peripherally on one surface of the peripheral area R2 of the package board 110 on which the semiconductor chip 10 is mounted is greater than the thickness t4 of the second peripheral circuit pattern 134 formed peripherally on the other surface of the peripheral area R2, heating the printed circuit board 200 together with the semiconductor chip 10 for the reflow process can make the package board 110 warp in the direction of the one surface, i.e., upwards, when temperature rises in the peripheral area R2 of the package board 110, as illustrated in FIG. 4. Since the first peripheral circuit pattern 124 and the second peripheral circuit pattern 134 are made of a metal, such as copper, the thermal expansion will be increased with an increased amount of the metal, and thus the bulging warpage occurs in the direction of the one surface of the package board 110 where there is a greater amount of metal.

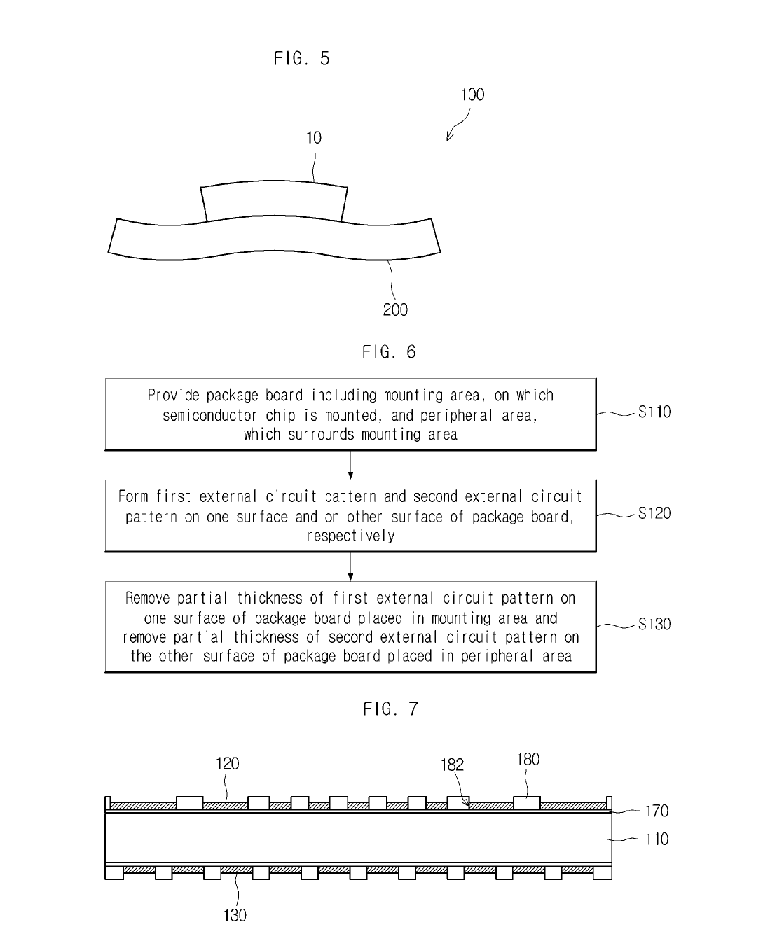

As shown in FIG. 5, when the semiconductor package 100 is at room temperature after the reflow process is completed, the semiconductor chip 10 and the mounting area R1 of the package board 110 can be warped to be slightly bulged upwards, unlike in FIG. 4, when heat is applied by the reflow process. In other words, since the package board 110 has a higher coefficient of thermal expansion than the semiconductor chip 10 and thus is contracted more than the semiconductor chip 10 when returned to room temperature, the mounting area R1 of the package board 110 and the semiconductor chip 10 mounted thereon can be warped to be bulged slightly upwards, unlike when heat was applied.

In the case of the present embodiment, although the peripheral area R2 of the package board 110 is warped to be bulged upwardly during the reflow process, as shown in FIG. 4, because the first peripheral circuit pattern 124 is formed to be thicker than the second peripheral circuit pattern 134, the peripheral area R2 of the package board 110 is not affected by the coefficient of thermal expansion of the semiconductor chip 10 and is contracted in an opposite fashion of the mounting area R1 when returned to room temperature after the reflow process. Therefore, the semiconductor package 100 at room temperature after the reflow process has less warpage and thus can nearly have an overall flat structure, as shown in FIG. 5.

On the contrary, in case the first peripheral circuit pattern 124 and the second peripheral circuit pattern 134 are formed to have a same thickness or the first peripheral circuit pattern 124 is formed to be thinner than the second peripheral circuit pattern 134 so as to correspond to the first central circuit pattern 122 and the second central circuit pattern 132, the peripheral area R2 of the package board 110 becomes warped to be bulged downwardly, like the mounting area R1 in the middle, during the reflow process and then becomes contracted in the same fashion as the mounting area R1 after the completion of the reflow process, allowing the semiconductor package 100 to generally have an upwardly bulged warpage at room temperature.

A thickness difference t341 between the first central circuit pattern 122 and the second central circuit pattern 132 can be configured to be same as a thickness difference t2-t4 between the first peripheral circuit pattern 124 and the second peripheral circuit pattern 134. Since symmetry can be provided for the warpage by heat by setting the thickness difference between the first central circuit pattern 122 and the second central circuit pattern 132 and between the first peripheral circuit pattern 124 and the second peripheral circuit pattern 134 to be the same, the overall warpage of the semiconductor package 100 can be significantly reduced at room temperature after the reflow process.

Moreover, it is possible to configure that the thickness t1 of the first central circuit pattern 122 is the same as the thickness t4 of the second peripheral circuit pattern 134 and that the thickness t3 of the second central circuit pattern 132 is the same as the thickness t2 of the first peripheral circuit pattern 124. As such, the symmetry of the warpage can be further improved by setting the thicknesses of these circuit patterns to be the same, in addition to setting the thickness difference between the first central circuit pattern 122 and the second central circuit pattern 132 and between the first peripheral circuit pattern 124 and the second peripheral circuit pattern 134 to be the same.

Furthermore, as shown in FIG. 1, solder resist layers 160 can be formed on either surface of the package board 110, openings are formed at areas of the solder resist layers 160 that correspond to pads. Specifically, the areas of the first central circuit pattern 122 corresponding to the pads are exposed and electrically contacted with the electrodes 12 of the semiconductor chip 10 by the solder 140, and the areas of the second peripheral circuit pattern 130 corresponding to the pads can also have solder 150 formed thereon for electrical contact with, for example, the motherboard.

Hereinafter, a method for manufacturing a printed circuit board 200 in accordance with another embodiment of the present invention will be described with reference to FIGS. 6 to 9.

As shown in FIGS. 6 to 9, the method for manufacturing the printed circuit board 200 in accordance with the present embodiment includes: providing a package board 110, which includes a mounting area R1, in which a semiconductor chip 10 is mounted, and a peripheral area R2, which surrounds the mounting area R1 (S110); forming a first external circuit pattern 120 and a second external circuit pattern 130 on one surface and on other surface of the package board 110, respectively (S120); and removing a partial thickness of the first external circuit pattern 120 on the one surface of the package board 110 placed in the mounting area R1 and removing a partial thickness of the second external circuit pattern 130 on the other surface of the package board 110 placed in the peripheral area R2 (S130).

Since the configurations and actions of the printed circuit board 200 manufactured according to the present embodiment have been described in detail through the above-described embodiment, the method for manufacturing the printed circuit board 200 will be mainly described hereinafter.

As shown in FIGS. 6 and 7, the package board 110, which includes the mounting area R1 having the semiconductor chip 10 mounted therein and the peripheral area R2 surrounding the mounting area R1, is provided (S110). The package board 110 can be divided into virtual areas of the mounting area R1 and the peripheral area R2 that correspond to the size of the semiconductor chip 10.

As shown in FIG. 7, the present embodiment presents that the package board 110 is constituted with a single layer and that seed layers 170 are formed on either surface of the package board 110 for forming the first external circuit pattern 120 and the second external circuit pattern 130.

Then, as shown in FIGS. 6 and 7, the first external circuit pattern 120 is formed on the one surface of the package board 110, and the second external circuit pattern 130 is formed on the other surface of the package board 110 (S120). This particular process can be described in two steps of forming a first resist 180 and filling in with a conductive material.

Specifically, the first resist 180 is formed on the seed layer 170 of the package board 110, and openings 182 are formed by exposing and developing so as to correspond to the first external circuit pattern 120 and the second external circuit pattern 130. Then, the openings 182 are filled with a conductive material by electroplating using the seed layers 170.

In such a case, the first external circuit pattern 120 and the second external circuit pattern 130 can be formed to have a same thickness, and the first external circuit pattern 120 and the second external circuit pattern 130 having the same thickness can be formed by electroplating both surfaces of the package board 110 simultaneously.

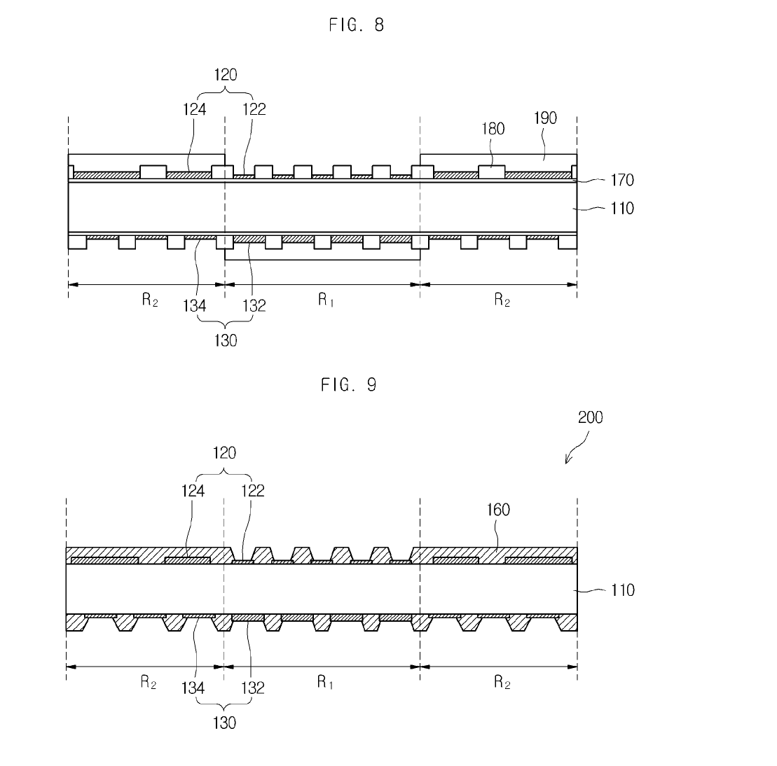

Afterwards, as illustrated in FIGS. 6 and 8, a partial thickness of the first external circuit pattern 120 on the one surface of the package board 110 corresponding to the position of the mounting area R1 is removed, and a partial thickness of the second external circuit pattern 130 on the other surface of the package board 110 corresponding to the peripheral area R2 is removed (S130). This process can be carried out by etching, more specifically, by partial etching.

That is, as shown in FIG. 8, whilst the first external circuit pattern 120 and the second external circuit pattern 130 are formed by plating, a second resist 190 is selectively formed an upper surface of the peripheral area R2 and a lower surface of the mounting area R1 of the package board 110, and then the thicknesses of the first external circuit pattern 120 and the second external circuit pattern 130 are partially removed by etching to form a first central circuit pattern 122 and a second peripheral circuit pattern 134.

In such a case, it is possible that the first external circuit pattern 120 and the second external circuit pattern 130 are removed by a same thickness, and accordingly it is possible that the first central circuit pattern and the second peripheral circuit pattern 134 are formed to have a same thickness and the second central circuit pattern 132 and the first peripheral circuit pattern 124 are formed to have a same thickness.

Afterwards, as shown in FIG. 9, the first resist 180 and the second resist 190 are removed, and the seed layer 170 that is exposed externally is removed by, for example, flash etching, and then openings are formed at areas of solder resist layers 160 corresponding to pads.

Although certain embodiments of the present invention have been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

1. A printed circuit board comprising:
a package board including a mounting area and a peripheral area, the mounting area having a semiconductor chip mounted therein, the peripheral area surrounding the mounting area;
a first central circuit pattern formed in the mounting area on one surface of the package board;
a second central circuit pattern formed in the mounting area on the other surface of the package board and having a greater thickness than the first central circuit pattern;
a first peripheral circuit pattern formed in the peripheral area on the one surface of the package board; and
a second peripheral circuit pattern formed in the peripheral area on the other surface of the package board and having a greater thickness than the second peripheral circuit pattern.

2. The printed circuit board of claim 1, wherein a difference in thickness between the first central circuit pattern and the second central circuit pattern is same as a difference in thickness between the first peripheral circuit pattern and the second peripheral circuit pattern.

3. The printed circuit board of claim 1, wherein a thickness of the first central circuit pattern and a thickness of the second peripheral circuit pattern are identical with each other, and
wherein a thickness of the second central circuit pattern and a thickness of the first peripheral circuit pattern are identical with each other.

4. The printed circuit board of claim 1, wherein the semiconductor chip is arranged in the mounting area on the one surface of the package board, and
wherein the first central circuit pattern is electrically connected with an electrode of the semiconductor chip by solder.

5. The printed circuit board of claim 4, wherein the electrode of the semiconductor chip is formed on a lower surface of the semiconductor chip, and the semiconductor chip is warped to be bulged downwardly when temperature rises,
wherein the mounting area is warped to be bulged toward the other surface of the package board, in a same direction as the semiconductor is warped, when temperature rises, and
wherein the peripheral area is warped to be bulged toward the one surface of the package board, in an opposite direction to warpage of the semiconductor, when temperature rises.

6. The printed circuit board of claim 1, wherein the package board comprises:
a plurality of insulation layers; and
an internal circuit pattern formed in between the plurality of insulation layers.

7. A semiconductor package comprising:
a semiconductor chip having an electrode formed thereon;
a package board including a mounting area and a peripheral area, the mounting area having the semiconductor chip mounted therein, the peripheral area surrounding the mounting area;
a first central circuit pattern formed in the mounting area on one surface of the package board;
a second central circuit pattern formed in the mounting area on the other surface of the package board and having a greater thickness than the first central circuit pattern;
a first peripheral circuit pattern formed in the peripheral area on the one surface of the package board; and
a second peripheral circuit pattern formed in the peripheral area on the other surface of the package board and having a greater thickness than the second peripheral circuit pattern.

8. The semiconductor package of claim 7, wherein a difference in thickness between the first central circuit pattern and the second central circuit pattern is same as a difference in thickness between the first peripheral circuit pattern and the second peripheral circuit pattern.

9. The semiconductor package of claim 7, wherein a thickness of the first central circuit pattern and a thickness of the second peripheral circuit pattern are identical with each other, and
wherein a thickness of the second central circuit pattern and a thickness of the first peripheral circuit pattern are identical with each other.

10. The semiconductor package of claim 7, wherein the semiconductor chip is arranged in the mounting area on the one surface of the package board, and
wherein the first central circuit pattern is electrically connected with an electrode of the semiconductor chip by solder.

11. The semiconductor package of claim 10, wherein the electrode of the semiconductor chip is formed on a lower surface of the semiconductor chip, and the semiconductor chip is warped to be bulged downwardly when temperature rises,
wherein the mounting area is warped to be bulged toward the other surface of the package board, in a same direction as the semiconductor is warped, when temperature rises, and
wherein the peripheral area is warped to be bulged toward the one surface of the package board, in an opposite direction to warpage of the semiconductor, when temperature rises.

12. The semiconductor package of claim 7, wherein the package board comprises:
a plurality of insulation layers; and
an internal circuit pattern formed in between the plurality of insulation layers.

13. A method for manufacturing a printed circuit board, comprising:
providing a package board, the package board including a mounting area and a peripheral area, the mounting area having a semiconductor chip mounted therein, the peripheral area surrounding the mounting area;
forming a first external circuit pattern and a second external circuit pattern on one surface and the other surface of the package board, respectively; and
removing a partial thickness of the first external circuit pattern placed in the mounting area on the one surface of the package board and removing a partial thickness of the second external circuit pattern placed in the peripheral area on the other surface of the package board.

14. The method of claim 13, wherein the first external circuit pattern and the second external circuit pattern are formed in a same thickness.

15. The method of claim 13, wherein the first external circuit pattern and the second external circuit pattern are removed by a same thickness.

16. The method of claim 13, wherein the forming of the first external circuit pattern and the second external circuit pattern comprises:
forming a resist on the one surface and the other surface of the package board, the resist having an opening formed therein so as to correspond to a position of the first external circuit pattern and the second external circuit pattern; and
filling in the opening with a conductive material by plating.

17. The method of claim 13, wherein the removing of the partial thickness of the first external circuit pattern and the second external circuit pattern is carried out by etching.
